(19) United States
(12) Patent Application Publication
(10) Pub. No.: US 2003/0051666 A1
(43) Pub. Date: Mar. 20, 2003

(54) Impedance adapted microwave energy coupling device

(76) Inventors: Rodney Moore, Gardner, MA (US); Hanno Kass, Darmstadt (DE); Wolf Essers, Weiterstadt (DE)

Correspondence Address: BURNS DOANE SWECKER & MATHIS L L P, POST OFFICE BOX 1404, ALEXANDRIA, VA, 22313-1404, US

(21) Appl. No.: 10/181,493

(22) PCT Filed: Jan. 11, 2001
(86) PCT No.: PCT/EP01/00257

(30) Foreign Application Priority Data
Jan. 19, 2000 (DE) 100 01 936.6

(51) Int. Cl. C23C 16/00

(52) U.S. Cl. 118/723 MW

(57) ABSTRACT

A device for coupling microwave energy into a treatment chamber (3) which is arranged in a hollow body (2), whereby said treatment chamber is a plasma CVD coating chamber for coating the inner wall of a hollow body (2). The inventive device comprises a microwave source, a microwave coupling device (10) and a microwave conductor (1,9). A gas supply tube (13) can be inserted into said hollow body (2) in such a way that a process gas can be activated into a plasma state by the coupled microwave energy. In order to treat hollow bodies (2) of different shapes and sizes without the need for substantial re-fitting each time, the gas supply tube (13) which is provided with the electrically conductive material extends into the wave guide from a first side in the form of an inner conductor of a coaxial wave guide (1 in region b) and the microwave coupling device (10) is arranged on the second side opposite, and an additional, electroconductive hollow conductor insert (12) in the form of a substantially hollow sleeve is disposed in the coaxial waveguide, coaxially surrounding the gas supply tube (13) at a distance therefrom.

The invention concerns an arrangement for coupling microwave energy into a treatment chamber disposed in a hollow body, in particular a plasma CVD coating chamber for coating the internal wail of a hollow body, comprising a microwave source, a microwave coupling-in device and a microwave guide, wherein a gas feed tube can be introduced into the interior of the hollow body in such a way that a process gas can be activated into the plasma state by the coupled-in microwave energy.

When coating hollow bodies, in particular plastic bottles, they are exposed in a coating chamber to the plasmas of a process gas. The quality of the coating depends inter alia on the impedance of the system for the microwave energy which is introduced. When variations occur in terms of the microwave radiation effect or impedance, the hollow bodies then have coatings of differing quality and thickness. The attempt has therefore been made to design a coupling arrangement with an electrically stable tuning effect, in which case even absorbent or scattering components of the coupling arrangement were taken into account.

In a coupling arrangement of the kind set forth in the opening part of this specification the microwave energy from the microwave source is coupled into the treatment chamber by way of a rectilinear microwave conductor or guide whose longitudinal axis crosses that of the treatment chamber and also that of the hollow body. That affords particular electrical conditions which inter alia for reasons of space is not suitable for an arrangement for coating a relatively large number of hollow bodies at the same time. Matching effects are made possible by means of screws and bars which are displaceable axially or transversely with respect to the microwave guide. It has been found that changes in impedance occur when treating different substrates, different configurations thereof and in particular when dealing with hollow bodies of different sizes and fluctuating shapes. If a first shape and size of hollow bodies was treated first, followed then by a second different shape and size, it was then difficult to concentrate the microwave energy in the same manner into regions where it is wanted for activation of the process gas to put it into the plasma state. It will be appreciated that it was possible, by virtue of using microwave guides of different configurations, to achieve the correct matching effect and to keep the impedance being considered appropriately the same from one batch to another. The change to other microwave guides however required a high level of expenditure.

There have also already been attempts at arranging magnets on the treatment chamber in order to concentrate the plasma to the correct locations in the hollow body. Storing, arranging and securing a plurality of magnets however is complicated and the magnets themselves experience a coating effect if they are arranged at the most effective location, namely in the treatment chamber.

Therefore the object of the present invention is to provide a coupling-in arrangement of the kind set forth in the opening part of this specification, by means of which hollow bodies of different configurations and sizes can be successively treated, at a low level of conversion expenditure.

In accordance with the invention that object is attained in that the gas feed tube comprising electrically conducting material extends from a first side as an internal conductor of a coaxial waveguide into said waveguide and the microwave coupling-in device is arranged on the opposite second side and that an additional, electrically conducting, substantially cylindrical hollow conductor insert is disposed in the coaxial waveguide, which surrounds the gas feed tube at a spacing in coaxial relationship. The entire coupling-in arrangement extends from a first side which to give a better idea can be referred to for example as the front or lower side, to an oppositely disposed second side which is then correspondingly provided at the rear or at the top in the arrangement. This arrangement therefore entails a central axis which extends from the first side to the second side, that is to say from the front rearwardly or from below upwardly. The gas feed tube extends in parallel relationship with that axis and in accordance with the invention is used as the internal conductor of the coaxial waveguide. Therefore that gas feed tube extends from the first side, that is to say from the front and below, along the axis upwardly into that coaxial waveguide. The microwave coupling-in device is provided in opposite relationship, that is to say on the upper second side of the arrangement. The hollow body to be treated embraces the gas feed tube at a spacing so that the notional axis of the arrangement also extends through the hollow body.

Admittedly, in the case of the invention, as also in the known arrangement, a process gas is introduced into the interior of the hollow body by means of the gas feed tube and the process gas is activated into the plasmas state by the coupled-in microwave energy. In the known case however the coupling-in direction is perpendicular to the above-mentioned axis through the hollow body so that the invention affords substantially better requirements in terms of a change in format of the hollow body.

When introducing a hollow body of a different format, that is to say a different size, different configuration etc., the impedance of the coupling-in arrangement changes with the result that unwanted reflection of the microwave energy occurs and only an excessively small proportion of the microwave energy that is fed in is available for activating the process gas to the plasma state. The change in impedance can now be adjusted by altering the waveguides surrounding the treatment chamber. It would be necessary for example to vary the spacing between the gas feed tube and the coaxial waveguide. An expensive change of that kind however is surprisingly avoided by means of the additional feature of the invention, namely that the additional electrically conducting hollow conductor insert is arranged at a spacing around the gas feed tube. The hollow conductor insert is of a smaller diameter than the external conductor, that is to say the coaxial waveguide. The hollow conductor insert is substantially cylindrical, in which respect it is possible to envisage all similar configurations, with certain modifications, for example slightly conical design configurations, interrupted or continuous design configurations, a grid or lattice form and so forth. The hollow conductor insert according to the invention varies the impedance when the second hollow body is of a different format, in such a way that it again appears to be the same as in the case of the first hollow body in respect of which matching in relation to the microwave energy was set at its optimum. It will be seen that it is substantially easier to fit a hollow conductor insert additionally into the coaxial waveguide, than replacing that waveguide itself by another. The assembly times and assembly expenditure are considerably less. Accordingly hollow bodies of different formats can be treated in succession without the need for the coupling-in arrangement to be converted in a time-consuming and costly fashion.

It is further advantageous in accordance with the invention if the second side of the coaxial waveguide is adjoined by the first side of an approximately cylindrical hollow conductor and provided at the second side thereof is the microwave coupling-in device. That arrangement affords a series of waveguides, by means of which the power is subject to a moderated reflection factor. Hollow bodies of unequal volumes and different configurations can then still be really effectively treated, for example coated, to a certain degree without further matching effects or changes in impedance. More specifically, this advantageous arrangement of the hollow conductor and the coaxial waveguide means that there is sufficient microwave power available for firing and maintaining the plasma. The successive arrangement of the two electrically different waveguide portions avoids mismatching phenomena to a greater degree than hitherto, and coupling-in of the microwave power is implemented with a high level of efficiency in that way.

It is also desirable in accordance with the invention if fitted in the cylindrical hollow conductor which is disposed on the second side of the arrangement is a quartz window which extends transversely with respect to the longitudinal axis of the arrangement. That quartz window practically represents a division or sealing means, and this is useful and readily possible precisely in the case of the above-described arrangement with the two waveguide portions. The axis which has already been described above, or longitudinal axis, extends in a line from the gas feed tube to the coupling-in device. The quartz window extends transversely with respect thereto and is a plate which is microwave-transmissive. Gases in contrast can be separated from each other by the quartz plate in such a way that a vacuum can be produced on one side while atmospheric pressure obtains on the other side.

It is particularly desirable if in accordance with the invention the hollow conductor insert has openings, if for example it is in the form of a grid basket or cage. Depending on the configuration and arrangement of the openings in the cylindrical hollow conductor insert, the impedance and field distribution can be varied and adapted to specific types of hollow body.

For technical reasons, as is known, the microwave frequency applied is fixed for example at about 2.5 GHz. That means however that the nature and dimensioning of microwave coupling into the waveguide is in turn practically fixed. By virtue of the arrangement of the new hollow conductor insert with the openings, it is possible to manage with few modifications when there is a change in format of the hollow body. The good coupling-in geometry, once established, does not require expensive conversion procedures for the waveguides, after the change in format. The coupling-in device in the cylindrical hollow conductor does not need to be further altered, once it has been optimised. Over and above arranging the hollow conductor insert which is to be suitably selected, there is no need for further tuning. The hollow conductor insert is deliberately arranged in the region of the coaxial waveguide so that, upon a change in format, the impedance is matched solely by changes in the coaxial portion.

It is particularly advantageous if, in accordance with the invention, the openings in the hollow conductor insert are slots extending in mutually parallel relationship. They can be mechanically produced really easily and can be disposed in different orientations, numbers and densities on the cylindrical hollow conductor insert. The openings and in particular the slots afford the particular advantage of permitting mode selection. As is known associated with each mode is a given specific distribution of electrical currents in the wall of the respective waveguide, for example therefore in the hollow conductor insert. If those wall currents are interrupted, the one associated mode or the other cannot be formed. Both TE- and also TM-modes can be propagated in a cylindrical hollow conductor. Together with TM-type modes wall currents are formed in parallel relationship with the axis of the cylinder while circular wall currents perpendicularly to said axis are associated with all TE-type modes.

If in a further advantageous configuration the slots extend perpendicularly to the axis of the hollow conductor insert, that is to say when the axis of the arrangement is deemed to be vertical, the slots therefore extend substantially horizontally, then only circular currents can still be formed in the wall of the hollow conductor insert so that consequently TE-type modes are formed.

In accordance with the invention another embodiment is characterised in that the slots are provided in homogeneously distributed fashion on the hollow conductor insert. When the hollow body to be treated is of an approximately uniform external shape and configuration, it is possible in that way to render uniform the distribution of the intensity of the electromagnetic field in the plasma and thus the result of the microwave treatment. Furthermore, in accordance with the invention, the arrangement can be so designed that on its one side the hollow conductor insert has a first ring and on the opposite side it has a group of second rings and all rings are held and connected together by at least one web or bar which extends in parallel relationship with the axis of the hollow conductor insert. A problem which arises from time to time is that of coating a plastic bottle from the inside thereof. At its end with its opening a bottle has a neck with a holding ring, possibly with a screwthread, so that, as viewed in relation to the volume, there is a greater accumulation of material than in the central region. The other end, namely the bottom, also involves in comparison with the centre a greater accumulation of material which can vary, depending on the respective configuration of the bottom. With the new hollow conductor insert according to the invention it is possible to concentrate the microwave energy at the bottom by way of the one first ring and in the region of the neck of the bottle (as an example) by way of the group of second rings, at the correct locations, with the consequence that the desired coating is achieved by the plasma in uniform fashion on the internal wall of the bottle or other container. The group of second rings comprises between 2 and 8 or preferably 4 rings which extend over a part of the bar length, for example over that part of the longitudinal extent of a bottle, in which the bottle tapers towards the neck and towards the opening thereof, with the region of the pouring opening of the bottle being arranged at the end of that group of rings.

If, in yet another embodiment, in accordance with the invention, the slots extend in parallel relationship with the axis of the hollow conductor insert and the pieces of material forming the slots are connected together by at least one ring, then in other words the slots extend in parallel relationship with the axis of the arrangement and consequently allow the formation of TM-modes. The ring is necessary for mechanical reasons in order to hold the strips of material forming the respective bars. On the other hand the arrangement of the ring can be utilised in order to apply the microwave energy at one end or the other or also at both ends of the hollow body to be treated, with the correct level of intensity.

It can be imagined that the strips of material which extend in parallel relationship with the axis are connected together and thereby held in place at both sides by a ring.

It had already been mentioned above that the arrangement, at the front first side, has a coaxial waveguide whose internal conductor is the metal gas feed tube. It has been found that coaxial waveguides permit the propagation of microwave energy in the TEM-type mode. Those modes do not have a lower limit frequency. Microwaves of relatively low frequencies can be propagated in a coaxial waveguide of relatively large diameter. Microwaves at those frequencies would be blocked in a non-coaxial guide but of the same diameter, because its limit frequency would be too high. In accordance with the invention therefore it is proposed for this embodiment that the coaxial waveguide is operated with microwaves only with TEM-type modes. A wide range of permitted frequencies is then available for operation. For a practical context, that in turn involves the advantage that, in the event of a change in format from a first hollow body to a second, a less drastic variation in impedance is found to occur and the arrangement according to the invention therefore guarantees treatment results of satisfactory quality for both hollow bodies.

In regard to the arrangement itself, the formation of the TEM-mode signifies that there is greater degree of freedom in terms of the choice of diameter of the hollow conductor insert. It can be selected not solely on the basis of electrical points of view, but it is also limited in a downward direction by the dimensions of the hollow body to be coated.

The invention teaches that, by virtue of suitable slotting of the walls of the hollow conductor insert and the mode selection that this entails, it is possible to achieve optimum coupling and field distribution by matching of the modes in the cylindrical hollow conductor and in the coaxial part.

Further advantages, features and possible uses of the present invention will be apparent from the description hereinafter of preferred embodiments. In the drawings:

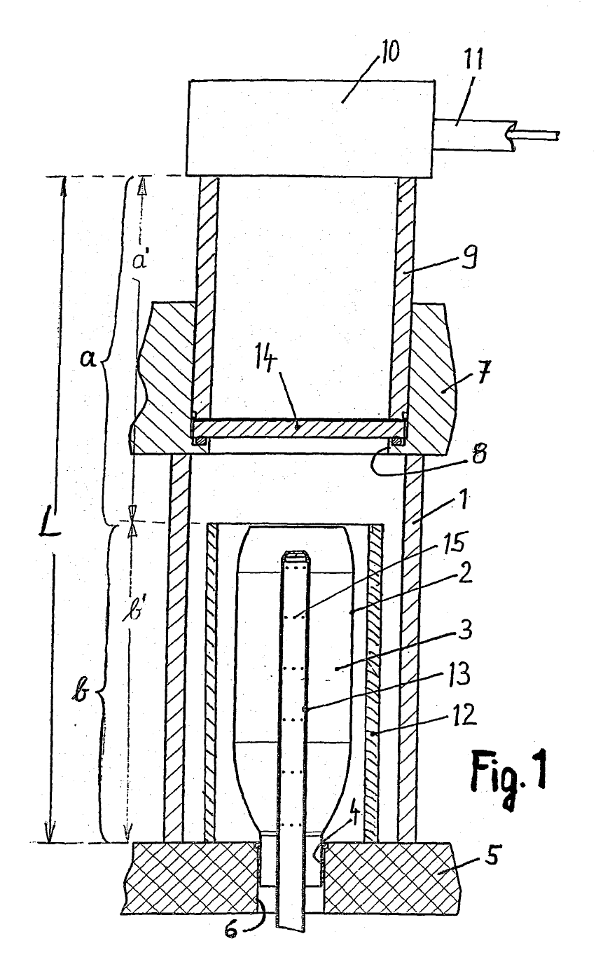

FIG. 1 is a partly broken-away diagrammatic view in cross-section through a coupling-in arrangement according to a first embodiment of the invention,

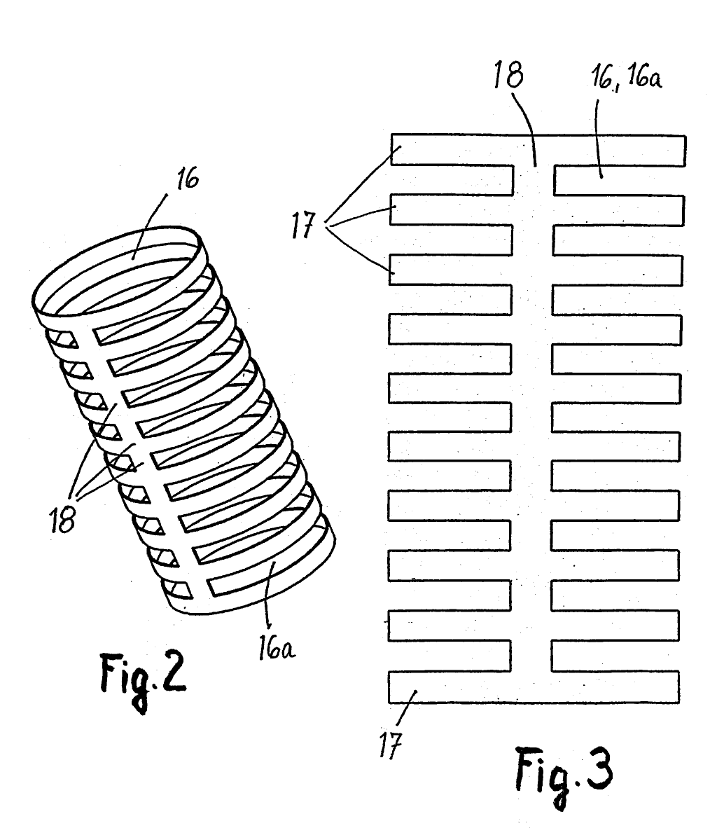

FIG. 2 shows a perspective view of a second form of a cylindrical hollow conductor insert with horizontally extending slots,

FIG. 3 is a side view of the hollow conductor insert of FIG. 2 viewing perpendicularly onto the vertically extending bar,

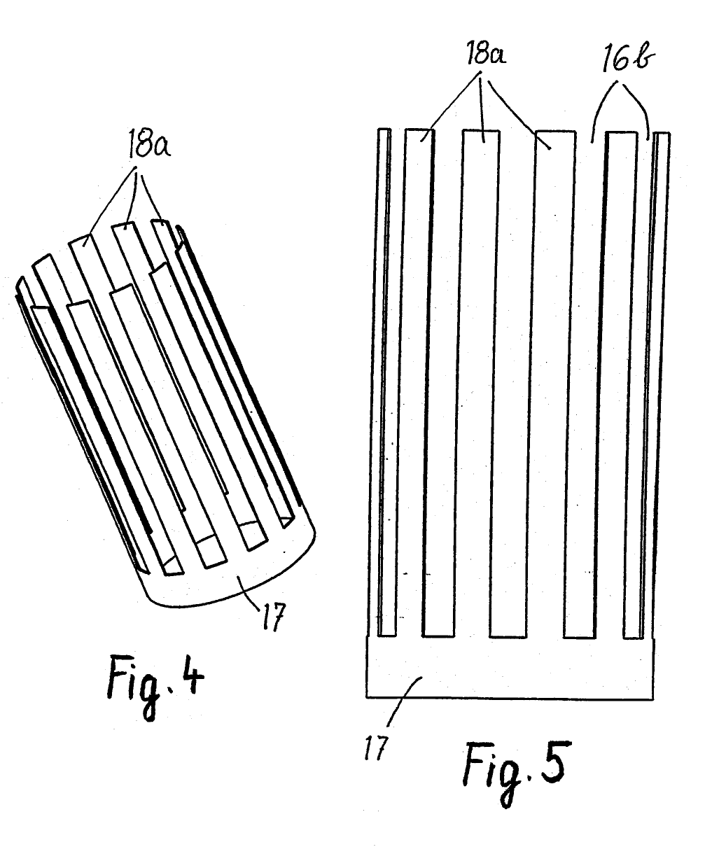

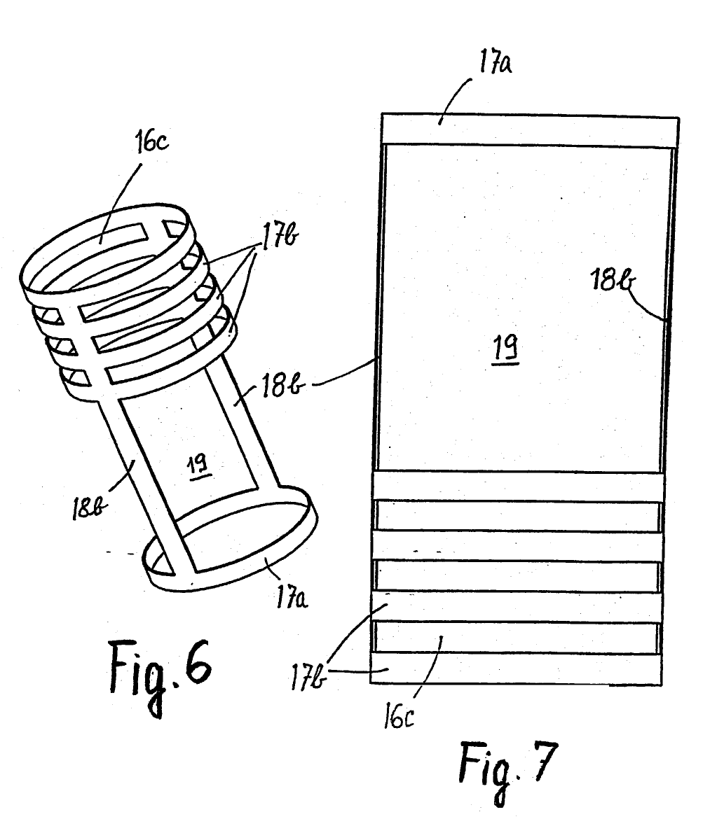

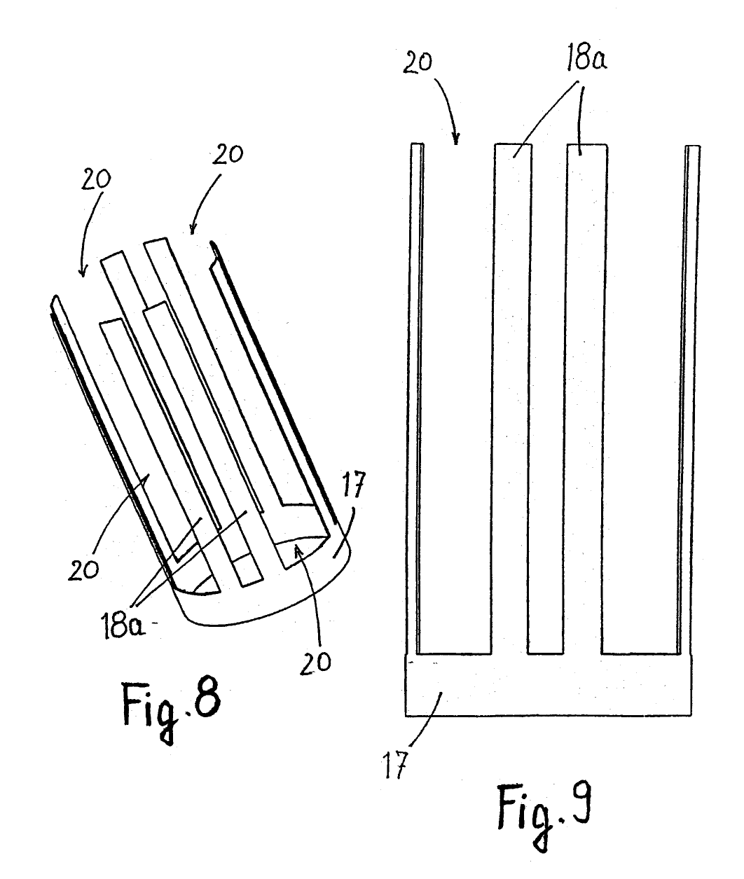

FIG. 4 is a perspective view of a third embodiment of a hollow conductor insert with vertically extending slots,

FIG. 5 is a side view of the hollow conductor insert of FIG. 4,

FIG. 6 is a perspective view of a fourth embodiment of a hollow conductor insert,

FIG. 7 is a view of the hollow conductor insert of FIG. 6 from the side in such a way that respective bars are to be seen at right and left with their narrow sides and the group of rings is arranged conversely at the bottom,

FIG. 8 is a perspective view of a fifth embodiment of a hollow conductor insert which is of a similar structure to FIG. 4, but wherein a respective bar is missing at each of the four locations identified by the arrows,

FIG. 9 shows a side view of the hollow conductor insert of FIG. 8,

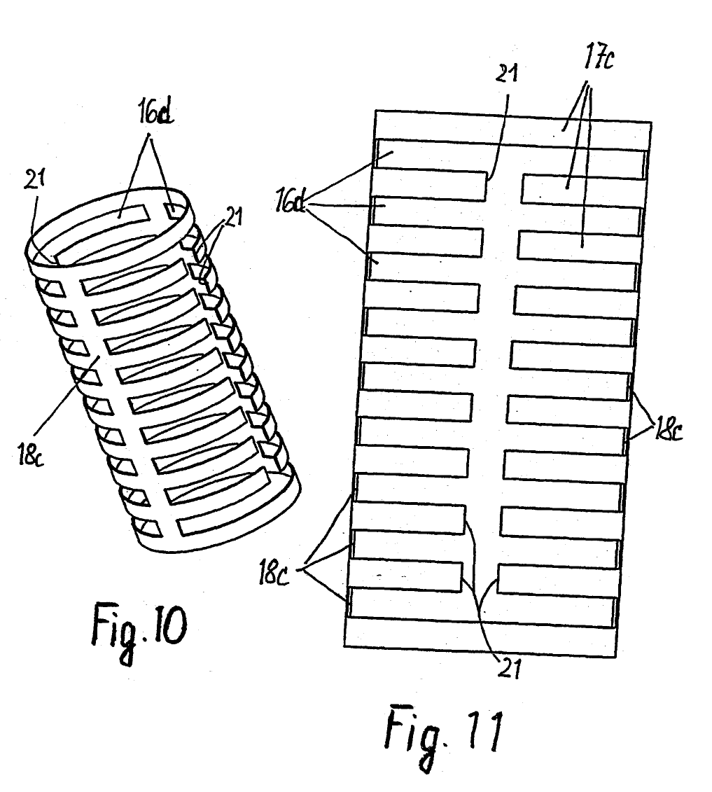

FIG. 10 is a perspective view of a sixth embodiment of a hollow conductor insert, and

FIG. 11 is a side view of the hollow conductor insert of FIG. 9, viewing the two vertically upstanding bars at the sides, with their narrow sides.

In FIG. 1 a hollow body 2 in the form of a plastic bottle is disposed in a cavity resonator 1. The hollow body 2 forms the treatment chamber 3 which is therefore in the interior of the hollow body 2. That can be for example a plasma CVD coating chamber for coating the internal wall of the hollow body 2. The hollow body 2 is open only at its front lower end, namely at its so-called first side, by way of a neck 4. At the top and rear the hollow body is closed, as also at the sides. The hollow body 2 is carried by way of its neck 4 by a container carrier plate 5. In the case of the embodiment of FIG. 1, the container carrier plate 5 is shown in broken-away form at the right and at the left. It is possible to imagine this plate as being of a longer extent so that many such units can be mounted in mutually juxtaposed relationship on the container carrier plate 5. A respective hole 6 in the container carrier plate 5 serves to receive the respective neck 4.

Upwardly and rearwardly towards the second side, at a spacing from the bottom of the hollow body 2, a separating wall 7 which extends substantially horizontally and parallel to the container carrier plate 5 is fixed to the cavity resonator 1. The longitudinal axis of the coupling-in arrangement is admittedly not shown in the Figures, but in each unit of which a single one is shown in FIG. 1, that longitudinal axis extends perpendicularly to the container carrier plate 5 and also perpendicularly to the separating wall 7, that is to say from the first side downwardly and forwardly to the second side upwardly and rearwardly, approximately vertically in the Figures. Provided in the separating wall 7 over each hollow body 2 is a hole 8 for receiving a cylindrical housing 9 which is closed off rearwardly and upwardly by a so-called microwave coupling-in device 10.

Fixed to the right of the microwave coupling-in device 10 in FIG. 1 is a microwave feed 11 which projects towards the right and outwardly of the housing 9. The microwave feed 11 is typically a coaxial cable or a coaxial waveguide and feeds the microwave coupling-in device 10. By means thereof, the microwave energy can be coupled into the cavity resonator 1 in the most widely varying ways, for example by way of an antenna (not shown here).

Overall, the space with the waveguides extends from the first side to the second side, that is to say from the front rearwardly (in the Figures, from below upwardly), from the internal surface of the container carrier plate 5 to the internal surface of the microwave coupling-in device 10. That space which is acted upon with microwaves is of a total length L. The arrangement of this substantially cylindrical structure is such that, considered electrically, on the second side, that is to say at the top in FIG. 1, in the region a there is an approximately cylindrical hollow conductor which does not have an internal conductor. Provided at the front first side (downwardly in the Figures) in the region b there is a coaxial waveguide. This has an internal conductor in the form of a gas feed tube 13.

Secured to the front lower end, that is to say at the first side of the cylindrical housing—still arranged in the separating wall 7—is a quartz window 14 by which the space in the cavity resonator 1 can be gas-tightly separated from the space in the housing 9 in such a way that the pressure of the gases contained in the housing 9 can be different from in the cavity resonator 1.

A gas mixture can be introduced into the treatment chamber 3 through the gas feed tube 13 and its holes 15 disposed therein, from the first side at the front and below in FIG. 1, in a manner not shown herein. That gas mixture for plasma formation remains within the volume of the hollow body 2, that is to say it remains in the treatment chamber 3. The so-called plasma region is then substantially within the front lower region b in the cavity resonator 1.

Disposed in the region b of the cavity resonator 1 therefore is the coaxial waveguide in which an electrically conducting, substantially cylindrical hollow conductor insert 12 is additionally disposed. This hollow conductor insert 12 surrounds the gas feed tube 13 at a spacing and is disposed in coaxial relationship with the gas feed tube and the cavity resonator 1. The hollow conductor insert 12 in FIG. 1 can for example be in the form of a hollow cylinder provided with a few openings (not shown here), possibly also in grid or lattice form.

The region a is determined by the spacing between the plane disposed at the top at its second side at the bottom of the hollow body 2 and the inside of the microwave coupling-in device 10. The spacing between those two planes which extend horizontally in FIG. 1 is therefore a′ while the length b′ of the region b is determined by the spacing between the inner flat surface of the container carrier plate 5 and the bottom of the hollow body 2. The overall length of the coupling-in arrangement L=a′+b′.

Devices for feeding the hollow body 2 with process gas are not shown, nor are devices for evacuating the spaces in question, into which fresh process gas is fed and from which consumed gas is removed. After filling of the treatment chamber 3 with process gas the microwave source is switched on and the process gas is activated to the plasma state. The exhausted gas is withdrawn after coating of the internal wall of the hollow body 2.

In order to implement activation of the process gas into the plasma state as intensively as possible, another hollow conductor insert 12 is fitted depending on the respective configuration of the hollow body 2 to be coated.

By way of example FIG. 2 shows a second embodiment of such a hollow conductor insert 12. All of FIGS. 2 to 10 show hollow conductor inserts 12, and for that reason the assembly is not repeatedly denoted by reference numeral 12 in all of the respective views. The hollow conductors of all embodiments as shown in FIGS. 2 to 10 have openings 16. In FIGS. 2 and 3 the openings 16 comprise slots 16a which extend in mutually parallel relationship. They extend in homogeneously distributed fashion over the entire height of the hollow conductor insert 12 and extend perpendicularly to the longitudinal centre line of the hollow conductor insert 12. The material between the slots 16a is formed by rings 17 which are held and connected together by a web or bar 18 which extends vertically and in parallel relationship with the longitudinal centre line.

The hollow conductor insert 12 shown in FIGS. 4 and 5 has only one ring 17 at one end, from which a plurality of bars 18a project. They all extend parallel and at the spacing of the slots 16b relative to each other. The slots 16b and also the bars 18a are therefore parallel to the axis of the hollow conductor insert 12.

In the embodiment shown in FIGS. 6 and 7, the hollow conductor insert 12 has a first ring 17a on its one side (downwardly in FIG. 6 and upwardly in FIG. 7) and a group of second rings 17b on the opposite side. Attached to the first ring 17a at diametrally opposite sides are two bars 18b which extend in parallel relationship with the longitudinal centre line of the hollow conductor insert 12 to the opposite side and thus to the group of the second rings 12. Both the rings 17a and also the second rings 17b are held and connected together by those two bars 18b. There is a free space 19 between the single first ring 17a and the group of second rings 17b, the group thereof being arranged at a spacing from the first ring 17a.

The hollow conductor insert 12 shown in FIGS. 8 and 9 is of a similar structure to that shown in FIGS. 4 and 5, wherein gaps 20 are formed only at the four locations identified by the arrows. There are therefore respective pairs of bars 18a between the gaps. Those four pairs of bars 18a are held together by the ring 17 at the one side which is shown downwardly in FIGS. 8 and 9.

The embodiment illustrated in FIGS. 10 and 11 involves a certain similarity to that of FIGS. 2 and 3, but slots 16d extending perpendicularly to the longitudinal centre line of the hollow conductor insert 12 are held by two bars 18c extending in parallel relationship with the longitudinal centre line of the hollow conductor insert 12. The rings 17c can therefore be interrupted except for the uppermost and the lowermost rings, as illustrated at the locations 21.

List of References

1 cavity resonator

2 hollow body

3 treatment chamber

4 neck

5 container carrier plate

6 hole

7 separating wall

8 hole

9 housing

10 microwave coupling-in device

11 microwave feed

12 hollow conductor insert

13 gas feed tube

14 quartz window

15 holes

16 openings

16a, b, c, d slots

17a, b, c rings

18a, b, c bars

19 gap

20 gaps

21 gap location

L overall length of the coupling-in arrangement

a upper region of the cavity resonator

b lower region of the cavity resonator

a′ length of the upper region of the cavity resonator

b′ length of the lower region of the cavity resonator

1. An arrangement for coupling microwave energy into a treatment chamber (3) disposed in a hollow body (2), in particular a plasma CVD coating chamber for coating the internal wall of a hollow body (2), comprising a microwave source, a microwave coupling-in device (10) and a microwave guide (1, 9), wherein a gas feed tube (13) can be introduced into the interior of the hollow body (2) in such a way that a process gas can be activated into the plasma state by the coupled-in microwave energy, characterised in that from a first side the gas feed tube (13) comprising electrically conducting material extends as an internal conductor of a coaxial waveguide (1 in the region b) into said waveguide and the microwave coupling-in device (10) is arranged on the opposite second side and that an additional, electrically conducting, substantially cylindrical hollow conductor insert (12) is disposed in the coaxial waveguide, which surrounds the gas feed tube (13) at a spacing in coaxial relationship.

2. An arrangement according to claim 1 characterised in that the second side of the coaxial waveguide (1 in the region b) is adjoined by the first side of an approximately cylindrical hollow conductor (1, 9 in the region a) and provided at its second side is the microwave coupling-in device (10).

3. An arrangement according to claim 1 or claim 2 characterised in that disposed in the cylindrical hollow conductor (9 in the region a) which is on the second side of the arrangement is a quartz window (14) which extends transversely with respect to the longitudinal axis of the arrangement.

4. An arrangement according to one of claims 1 to 3 characterised in that the hollow conductor insert (12) has openings.

5. An arrangement according to one of claims 1 to 4 characterised in that the openings (16) in the hollow conductor insert (12) are slots extending in mutually parallel relationship.

6. An arrangement according to one of claims 1 to 5 characterised in that the slots (16a) extend perpendicularly to the axis of the hollow conductor insert (12).

7. An arrangement according to one of claims 1 to 6 characterised in that the slots (16a) are disposed homogeneously distributed on the hollow conductor insert (12).

8. An arrangement according to one of claims 1 to 7 characterised in that the hollow conductor insert (12) has on its one side a first ring (17a) and on the opposite side a group of second rings (17b) and all rings are held and connected together by at least one bar (18b) extending in parallel relationship with the axis of the hollow conductor insert (12).

9. An arrangement according to one of claims 1 to 8 characterised in that the slots (16b) extend in parallel relationship with the axis of the hollow conductor insert (12) and the material is held together between the slots (16b) by at least one ring (17)
